(19) United States
(12) Patent Application Publication
(10) Pub. No.: US 2024/0355683 A1
(43) Pub. Date: Oct. 24, 2024

(54) METHOD OF METROLOGY ON PATTERN WAFER USING REFLECTOMETRY

(71) Applicant: Applied Materials, Inc., Santa Clara, CA (US)

(72) Inventor: Khokan C. PAUL, Cupertino, CA (US)

(21) Appl. No.: 18/306,187

(22) Filed: Apr. 24, 2023

(51) Int. Cl. H01L 21/66

(52) U.S. Cl. CPC H01L 22/12; H01L 21/76224

(57) ABSTRACT

The present disclosure generally relate to an apparatus and method for metrology of properties and thicknesses of films selectively deposited on a substrate, such as a patterned substrate. In one embodiment, the method includes placing a substrate in a process chamber having an in-situ reflectometry system integrated therein and establishing a reference data set using the in-situ reflectometry system for a selected region of the substrate. The substrate is then processed in the process chamber in which a film is selectively deposited on the selected region of the substrate. A thickness of the film deposited on the selected region may then be determined and/or monitored using the in-situ reflectometry system based on the reference data set.

### BACKGROUND

### Field

Embodiments of the present disclosure generally relate to methods for measuring properties and thicknesses of films selectively deposited on a substrate.

### Description of the Related Art

Film thickness measurements of a processed substrate can be used in relation to processing operations. Generally, film thickness measurements are taken outside of a process chamber in which the processed substrate is processed, after the processing operations are conducted. Such measurement determinations can involve inefficiencies and reduced throughput, as substrates which do not meet specifications may not be used, and it can take several processing iterations to obtain measurements that meet specifications. Additionally, it is difficult to conduct film thickness measurements within the process chamber and during the processing operations because processing equipment in the process chamber can interfere with measurement equipment, thereby hindering measurement accuracy. For example, heat emitted from heat lamps can interfere with measurement equipment. As another example, windows in a process chamber may accumulate material thereon during processing, interfering with measurement accuracy.

When measuring film thickness or other properties using conventional reflectometry, properties of the substrate underneath the thin film being measured are needed for calculating the properties of the thin film being measured. However, in semiconductor processing, process chambers are usually used for depositing films on various substrates including substrates having a patterned surface. For example, patterned substrates may be used in connection with selective deposition processes for depositing films in certain regions of the patterned substrate, such as in trenches formed on the surface of the patterned substrate, and Epitaxial source/drain deposition (viz., HS SiP, SiGeB, SiGe, etc). Often times, the surface properties of specific portions of the patterned substrates underneath the point of the thin film being measured are not known. When measuring films on patterned substrates, even if the pattern is known, the point being measured may not fall in the same region of the pattern for each substrate being measured.

Therefore, there is a need for improved apparatus, systems, and methods that facilitate in-situ and real-time measurement operations at specific substrate locations having unknown surface properties.

### SUMMARY

The present disclosure generally relates to methods for measuring properties and thicknesses of films selectively deposited on a substrate, such as a patterned substrate. In some embodiments, a method is provided for measuring film thickness on a substrate via in-situ reflectometry. The method includes placing a substrate on a substrate support in a process chamber having an in-situ reflectometry system integrated with the process chamber and establishing a reference data set via in-situ reflectometry using the in-situ reflectometry system for a selected region of the substrate. Next, the substrate is processed in the process chamber in which a film is selectively deposited on the selected region of the substrate. The method then continues with establishing a measurement data set via in-situ reflectometry using the in-situ reflectometry system for the film deposited on the selected region of the substrate, and determining a thickness of the film by comparing the measurement data set with the reference data set.

In another embodiment, a method is provided for measuring film properties on a substrate via reflectometry using a standalone or on-board metrology assembly. The method includes disposing a substrate in an on-board metrology housing having an on-board metrology assembly and establishing a reference data set via reflectometry using the on-board metrology assembly for a selected region of the substrate. After the reference data set is obtained, the method continues with transferring the substrate from the on-board metrology housing to a process chamber and processing the substrate by selectively depositing a film on a surface of the substrate at the selected region. After processing of the substrate is complete, the substrate is transferred from the process chamber to the on-board metrology housing. The method then continues with establishing a measurement data set via reflectometry using the on-board metrology assembly for the film deposited at the selected region of the substrate, and determining a thickness of the film by comparing the measurement data set with the reference data set.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of an exemplary process chamber with an in-situ reflectometry (ISR) system, according certain embodiments.

FIG. 2 is a partial schematic cross-sectional view of the in-situ reflectometry system depicted in FIG. 1, according certain embodiments.

FIG. 3 is a schematic cross-sectional view of an exemplary on-board metrology assembly, according certain embodiments.

FIG. 4 is a flow diagram of an exemplary method for measuring via in-situ reflectometry in a process chamber thickness of a thin film selectively deposited on a patterned substrate using the in-situ reflectometry system depicted in FIGS. 1 and 2, according to certain embodiments.

FIGS. 5A through 5F show cross-sectional views of a thin film selectively deposited on a patterned substrate and measured via in-situ reflectometry, according to certain embodiments.

FIG. 6 is a flow diagram of an exemplary method for measuring via reflectometry thickness of a thin film selectively deposited on a patterned substrate using the on-board metrology assembly shown in FIG. 3, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods of metrology on patterned substrates when surface properties of the substrate are unknown. In some embodiments, the methods may be applied and performed for in-situ measurements in process chambers, such as epitaxial process chambers, having integrated in-situ reflectometry for real time metrology and process monitoring. In other embodiments, the methods may be performed outside of the process chamber via on-board metrology (OBM) assembly or standalone metrology. In such embodiments, adjustments to the substrate orientation may be made without unloading and loading the substrate from the process chamber, but measurements are made after the deposition process is completed as opposed to real time.

Specifically, unlike chemical vapor deposition (CVD), metrology is not commonly used in epitaxial chambers due to the issues created by the directional cross-flows across the surface of a substrate during epitaxial deposition. CVD processes deposit material uniformly perpendicular to the major plane of the substrate in line with a metrology based sensor, whereas an epitaxial deposition passes material perpendicular to a sensor and historically causes issues for real time film thickness analysis.

During processing, light from a substrate may be monitored as material is deposited on the substrate. The light is collected and analyzed by a spectrometer, computing device, and/or other light measuring apparatuses to facilitate determination of substrate properties, such as thin film thickness, thin film deposition rate, thin film optical properties and/or in-film concentration of Ge, B, P, and/or Ar etc. Multiple measurements, for example, thin film thickness, think film deposition rate, and/or substrate temperature, can occur simultaneously using one or more measuring apparatuses.

In certain embodiments, the methods may be applied and performed for in-situ measurements of thin films deposited by selective processes, such as in processing of patterned substrates with unknown substrate properties. For example, patterned substrate may be non-planar and the properties of the patterned substrates such as film composition, sheet resistance, particle count, and film stress may also be unknown. In some embodiments, the methods discussed herein may be applied for in-situ reflectometry measurements of thin films selectively deposited on a portion of a patterned substrate with an open area of about 5%. In other embodiments, the methods discussed herein may be applied for in-situ reflectometry measurements of thin films selectively deposited on a portion of a patterned substrate with an open area greater than 5%, such as between 5% and 10%, or less than 5%, such as about 1%. Such methods may also be performed inside a process chamber via an integrated in-situ reflectometry system during or after processing of the substrate, or outside of the process chamber via an on-board metrology (OBM) assembly utilizing reflectometry (e.g., in-situ reflectometry type system) after the processing of the substrate.

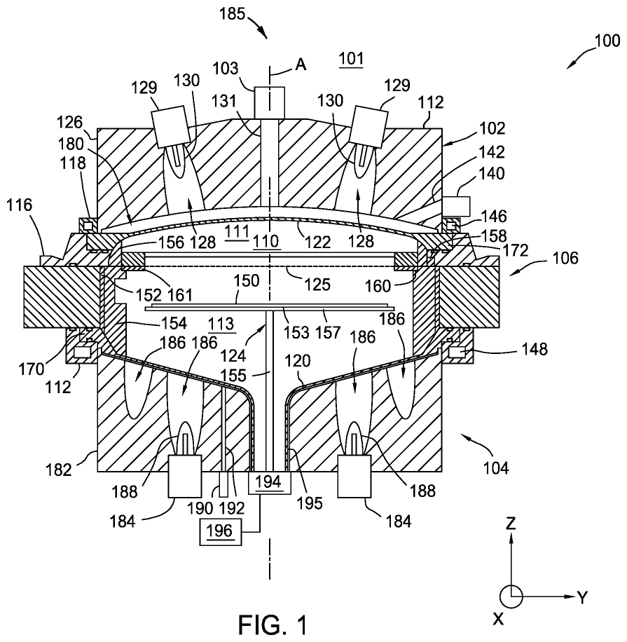

FIG. 1 is a schematic cross-sectional view of a process chamber 100 with an integrated in-situ reflectometry system, according to certain embodiments. The process chamber 100 may be an epitaxial deposition chamber utilized to grow an epitaxial film on a substrate, such as the substrate 150. In some embodiments, process chamber 100 may be used as part of a cluster tool. In certain embodiments, substrate 150 includes a patterned surface upon which material may be selectively deposited on during an epitaxial process. The process chamber 100 creates a cross-flow of precursors (e.g., process gases) and etchants across the top surface of the substrate 150 during processing for selective epitaxial growth on the patterned surface of substrate 150. The aspects and benefits of the present disclosure may be used for other selective substrate processing operations, such as in chemical vapor deposition (CVD) chambers, atomic layer deposition (ALD) chambers, physical vapor deposition (PVD) chambers, etch chambers, ion implantation chambers, oxidation chambers, and/or other processing chambers.

The process chamber 100 includes an upper housing module 102, a lower housing module 104, a chamber body assembly 106, a susceptor assembly 124, a lower window 120, and an upper window 122. The upper housing module 102 can also be a lid or part of a process chamber lid. The susceptor assembly 124 is disposed between the susceptor assembly 124 and the lower housing module 104. The lower window 120 is disposed between the susceptor assembly 124 and the lower housing module 104. The upper window 122 is disposed between the susceptor assembly 124 and the upper housing module 102.

The upper housing module 102 is disposed over the susceptor assembly 124 and configured to heat a substrate, such as the substrate 150, disposed on the susceptor assembly 124. The upper housing module 102 includes an upper module body 126 and a plurality of lamp apertures 128 disposed through the upper module body 126. Each of the plurality of lamp apertures 128 includes an upper lamp 130 disposed therein coupled to a lamp base 129. Each of the lamp bases 129 supports one of the upper lamps 130 and electrically couples each of the upper lamps 130 to a power source (not shown). Each of the lamp bases 129 and the upper lamps 130 coupled thereto are secured in a generally vertical orientation within the apertures 128. As described herein, the general vertical orientation of the upper lamps 130 is approximately perpendicular to the substrate support surface of the susceptor assembly 124. However, other orientations are also contemplated.

The upper housing module 102 includes a pyrometer passage 131 (for example, a light pipe). The pyrometer passage 131 may be a centrally-located within the upper housing module 102. The pyrometer passage 131 extends through the upper module body 126 from a first (e.g., lower) surface of the upper module body 114 to a second (e.g., upper) surface of the upper module body 126. The pyrometer passage 131 is configured to allow light to travel between the surface of the substrate 150 (or the surface of a thin film deposited thereon) and an in-situ reflectometry (ISR) system 185.

An upper plenum 180 is defined between the bottom surface of the upper module body 126 and the upper window 122. Heated gas is supplied to the upper plenum 180. A heated gas exhaust passage 142 is also disposed through the upper module body 126. The heated gas exhaust passage 142 is coupled to a heated exhaust pump 140. The heated exhaust pump 140 removes gas from the upper plenum 180.

The lower housing module 104 is disposed below the susceptor assembly 124 and configured to heat a bottom side of the substrate 150 disposed on the susceptor assembly 124. The lower housing module 104 includes a lower module body 182 and a plurality of lamp apertures 186 disposed through the lower module body 182. Each of the plurality of lamp apertures 186 includes a lower lamp 188 disposed therein. Each of the lower lamps 188 are disposed in a generally vertical orientation and coupled to a lamp base 184. Each of the lamp bases 184 supports one of the lower lamps 188 and electrically coupled each of the lower lamps 188 to a power source. As described herein, the generally vertical orientation of the lower lamps 188 is described with respect to a substrate support surface of the susceptor assembly 124.

During the substrate processing operation, the upper lamps 130 are powered to generate radiant energy (e.g. heat) and direct the radiant energy toward the substrate 150 and the susceptor 157. During the substrate processing operation, the lower lamps 188 are powered to generate radiant energy upwardly toward the substrate 150 and the susceptor 157.

The lower lamp module 104 includes a susceptor shaft passage 195 and a pyrometer passage 192. A support shaft 155 of the susceptor assembly 124 is disposed through the susceptor shaft passage 195. The susceptor shaft passage 195 is disposed centrally through the lower module body 182. The susceptor shaft passage 195 allows the support shaft 155 of the susceptor assembly 124 and a portion of the lower window 120 to pass through the lower module body 182.

The pyrometer passage 192 is disposed through the lower module body 182 outward of the susceptor shaft passage 195 to enable a lower pyrometer 190, such as a scanning pyrometer, to measure the temperature of the bottom surface of the substrate 150 or a bottom surface of a susceptor 157 of the susceptor assembly 124. The lower pyrometer 190 is disposed below the lower module body 182 adjacent to the pyrometer passage 192. The pyrometer passage 192 extends from the bottom surface of the lower module body 182 to the top surface of the lower module body 182.

The process chamber 100 includes a process volume 110 having an upper chamber volume 111 and a lower chamber volume 113. The substrate 150 is loaded onto (or removed from) the susceptor assembly 124 in the lower chamber volume 113 for processing in the upper chamber volume 111. The susceptor assembly 124 is shown in a lower position (e.g., a loading position for the substrate 150) in FIG. 1. The processing position is the position wherein the substrate 150 is disposed even with or above the horizontal plane 125. The upper chamber volume 111 and the lower chamber volume 113 may be understood as the volume above and below the susceptor 157, respectively, while the susceptor assembly 124 is in the processing position.

An upper cooling ring 118 and a lower cooling ring 112 are disposed on opposite sides of the chamber body assembly 106. The upper cooling ring 118 is disposed on top of an inject ring 116 and is configured to cool the inject ring 116. The use of the upper cooling ring 118 and the lower cooling ring 112 can reduce the temperature of the inject ring 116 without the need for additional cooling channels being disposed through the inject ring 116. Using the upper cooling ring 118 and the lower cooling ring 112 reduces the cost of the production of the inject ring 116, which can be more frequently replaced than the upper cooling ring 118 and the lower cooling ring 112. The present disclosure contemplates that the inject ring 116 can include one or more additional cooling passages formed therein.

One or more gas injectors 108 are disposed through one or more openings within the inject ring 116 to provide gases, such as process gases, to the process volume 110. Each of the one or more gas injectors 108 may be positioned at an angle of greater than about 4° from an X-Y plane of the substrate 150, such as greater than about 10° from the X-Y plane. Each of the injectors 108 are fluidly coupled to one or more process gas supply sources, such as the first process gas supply source and/or the second process gas supply source. In some embodiments, only a first process gas supply source is utilized. In some embodiments in which both the first process gas supply source and the second process gas supply source are utilized, there can be two gas outlets within each gas injector. According to some embodiments, which can be combined with other embodiments, the first process gas supply source is a process gas while the second process gas supply source is a cleaning gas. The cleaning gas can be used to clean features of the ISR system 185 in the process volume 110 and/or features of the reflectometer system in the process volume 110.

A variety of liners and heaters are disposed inside of the chamber body assembly 106 and within the process volume 110. As shown in FIG. 1, an upper liner 156 and a lower liner 154 are disposed within the chamber body assembly 106. The upper liner 156 and the lower liner 154 are configured to shield the inner surfaces of the inject ring 116 from the process gases within the process volume 110. The upper liner 156 and the lower liner 154 further serve to reduce heat loss from the process volume 110 to the inject ring 116. Reduced heat loss improves heating uniformity of the substrate 150 and enables more uniform deposition on the substrate 150 during processing operations (e.g., the epitaxial deposition operations). A preheat ring 161 is supported on a ledge 160 of the lower liner 154. The preheat ring 161 and the edge of the substrate are located within a radially outward area of the process volume 110.

An upper heater 158 and a lower heater 152 are also disposed within the chamber body assembly 106 and the process volume 110. As shown in FIG. 1, the upper heater 158 is disposed between the upper liner 156 and the inject ring 116 while the lower heater 152 is disposed between the lower liner 154. Both of the upper heater 158 and the lower heater 152 are disposed inward of the chamber body assembly 106 to enable more uniform heating of the substrate 150 while the substrate 150 is within the process chamber 100.

The susceptor assembly 124 disposed within the process volume 110 may be configured to support and rotate the substrate 150 during processing. A controller 196 may be used to control the susceptor assembly 124 to rotate the substrate 150 disposed thereon during the processing of the substrate 150. The susceptor assembly 124 includes a planar substrate support surface 153 for supporting the substrate 150 and is coupled to a movement assembly 194 via a shaft 155. The movement assembly 194 includes for examples, one or more motors or actuators for inducing at least rotation (step or continuous) about a central axis, axis A, vertical movement of the susceptor assembly 124, angular tilt of the susceptor assembly 124, or other movement.

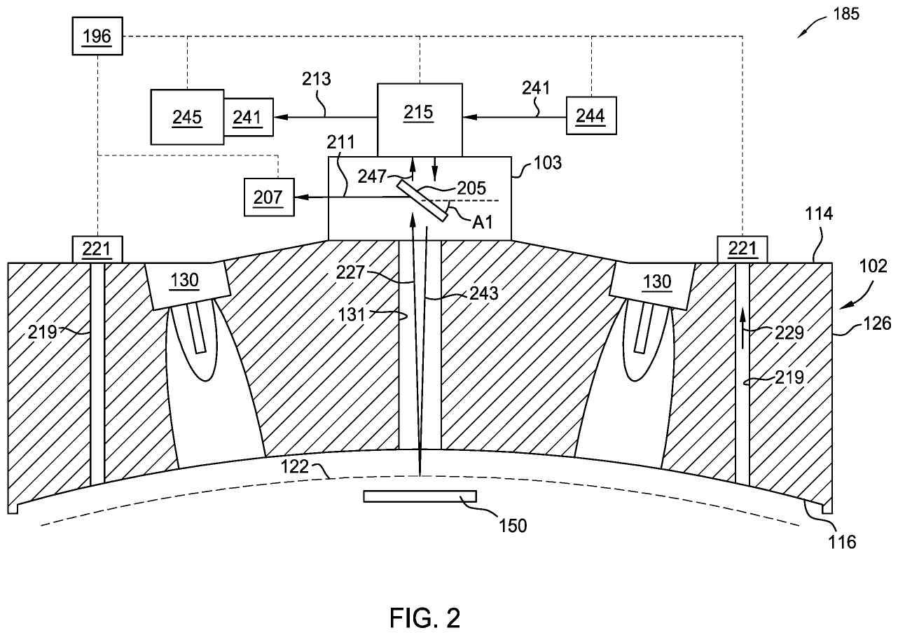

FIG. 2 is a partial schematic cross-sectional view of the ISR System 185 connected to the process chamber 100 and disposed above the upper housing module 102, as shown in FIG. 1, according to certain embodiments. The ISR system 185 includes a housing 103 that houses one or more optical elements therein to facilitate processing of optical signals. The ISR System 185 includes a light source 244, a collimator 215, sensor 245, a pyrometer 207, one or more additional sensors 221 (two are shown), and a dichroic mirror 205 coupled to or disposed above the upper housing module 102. In some embodiments, the ISR System 185 facilitates in-situ measurements of a thickness of a thin film deposited on the substrate 150. In certain embodiments, the ISR system 185 may be used to measure a thickness of a thin film selectively deposited on a portion of the substrate 150. In other embodiments, the ISR System 185 may be used to measure a thickness of a thin film deposited on the substrate 150 via a non-selective process. Alternatively, in some embodiments, the ISR System 185 may be used to measure other properties of the substrate 150 (and/or a thin film disposed thereon) such as temperature, thin film growth rate, thin film optical properties, and/or in-film Ge concentration.

The light source 244 is configured to generate a light 241. In some embodiment, the light source 244 may be a flash lamp capable of producing full spectrum or partial spectrum light. In one example, the spectrum of light generated has a wavelength between about 200 nm to about 4 micrometers, such as 200 nm to about 800 nm and/or 3 micrometers to 4 micrometers. Full spectrum light allows for a wide range of light signals for analysis, however in other embodiments a light source may be limited to a specific wave length of light or specific range of light wave lengths to accomplish the analysis. The light source 244 may be controlled by the controller 196. The light source 244 is in optical communication with the collimator 215. Optical communication includes being connected by a fiber optic cable, but other modes of light transmission are contemplated. The travel path of the light from the light source 244 may be referred to as a propagation path. Light from the light source 244 may be directed to the collimator 215. Collimated light 243 from the collimator 215 then travels through a pyrometer passage 131 to the surface of the substrate 150 (or a thin film thereon) to facilitate measurement of one or more properties of the substrate 150 (or a thin film thereon). The pyrometer passage 131 can be a made of any material capable of transmitting light of predetermined wavelengths, for example, sapphire. In addition to, or as an alternative to, measurement of the substrate 150 (or a thin film deposited thereon), it is contemplated that a coupon surface on the preheat ring 161 (or other surface) could also be measured by a sensor appropriately configured and placed. In some embodiments, the substrate 150, susceptor surface, or coupon surface may be measured to establish an initial data set for a calibration metric.

The collimated light 243 is reflected off a target measurement surface, such as a surface of a thin film (not shown) selectively deposited on the substrate 150, and reflected back towards the ISR system 185 as a reflected light 227. The reflected light 227 travels back through the pyrometer passage 131 to the dichroic mirror 205 and split with a portion of the reflected light 227 reflected by the dichroic mirror 205 and a portion of the reflected light 227 passing therethrough. The reflected portion from the dichroic mirror 205 is transmitted to a pyrometer 207. According to some embodiments, only light wavelengths between about 1.0 μm and about 5.0 μm, such as between about 3.0 μm and about 4.0 μm, travel along light path 211 to a pyrometer 207.

According to certain embodiments, the dichroic mirror 205 is a transparent material with a dielectric coating. The dielectric coating may include, but is not limited to, magnesium fluoride, tantalum pentoxide, and titanium dioxide. The dichroic mirror 205 reflects certain wavelengths of light away, but allows other specifically selected wavelengths to pass through. A wavelength range directed to a sensor 245 may be between about, 100 nm and about 1000 nm, such as within a range of 200 nm and 800 nm, such as within a range of 200 nm and 400 nm, and such as within a range of 400 nm and 800 nm. The dichroic mirror 205 enables multiple light based sensors to be utilized by directing light of a first desired range of to one sensor with the remaining light wavelengths being sent to at least another sensor. Thus, the ISR system 185 provides a compact measurement system, allowing more sensors to be included in a smaller footprint. The dichroic mirror 205 is arranged, or oriented, at an angle of incidence A1 between about, 30° and about 50°, such as within a range of 35° and 45°, with a plane near orthogonal to a longitudinal axis of the pyrometer passage 131. However, other angles of incidence are contemplated.

As noted above, properties of the dichroic mirror 205 may be selected to transmit or reflect light in specified wavelength ranges. The portion of reflected light 243 allowed to pass through the dichroic mirror 205 is collimated by the collimator 215 as collimated light 213. The collimated light 213 is then directed to the sensor 245. In some embodiments, the sensor 245 may be an optical spectrometer or a spectrograph configured to measure a wavelength-resolved intensity of the collimated light 213. The sensor 245 can additionally include a grating, an optical lens, a filter, a linear-array photodiode detector, and/or a charged-coupled device (CCD) detector. In some embodiments, sensor 245 includes a short pass filter to limit the noise from a lamp 128, or a dielectric filter. A dielectric filter includes any thin film based filters than can prevent specific wavelength of light from passing therethrough.

While the filter is described as part of the sensor 245, it is contemplated that the filter can be located in other locations. For example, the filter can be part of the dichroic mirror 205. The filter is configured to allow light only of a specified wavelength to pass therethrough. In one example, the filter only allows light of wavelengths below 450 nm to pass therethrough to mitigate light signal noise from lamps of the process chamber, thus improving measurement accuracy. It is contemplated that the filter can be placed in any light path that includes the light reflected off the substrate 150 (e.g., reflected light 227, to the sensor 245) (e.g., reflected light 247 from dichroic mirror 205) (e.g., collimated light 243). In one example, the filter is an integral component of sensor 245, but in other examples, the filter is a standalone component from the sensor 245. According to some embodiments, the filter is not included in the path, reducing the cost, complexity, and footprint of ISR system 185. It is to be noted that while embodiments described herein may include a filter and/or a dichroic mirror 205, both the filter and the dichroic mirror 205 are optional and may be excluded from any embodiment or implementation described herein, as benefits may be achieved in the absence thereof.

As mentioned above, the ISR system 185 may optionally include one or more additional sensors 221 positioned in the upper housing module 102 to receive data from other portions of the substrate 150, such as the edge portion of the substrate 150. Alternatively, additional sensors may be configured and positioned to be in view of other portions of the substrate 150 to receive data for measuring a thin film selectively deposited on certain other portions of the substrate 150. The sensors 221 may be implemented alone or in combination with a pyrometer for dome application. Each sensor 221 is configured to be in line (e.g., vertically and/or optically aligned) with a sensor passage 219. The sensor passage 219 may extend through the upper module body 126 and is configured to allow a light 229 to travel between the surface of the substrate 150 and the ISR System 185. The reflected signal from the substrate 150 may also be directed and collected at right-angle or other adaptable angular orientation, based on the hardware integration suitability.

In some embodiments, the sensor 221 is a spectrometer or a channel of a multi-channel spectrometer configured to measure a property of a portion of the substrate 150 (or thin film disposed thereon). In other embodiments, the sensor 221 may be used to measure a property of the preheat ring 161 (and/or a coupon disposed thereon). In one example, the sensor 221 may be configured to read a reference material within or on the preheat ring 161 for use as a thin film thickness reference. For example, the reference material can be a crystalline coupon of known properties.

Each sensor passage 219 extends between the bottom surface and the upper surface of the upper module body 126. The sensor passage 219 may be vertically aligned with (and/or directed at) portions of the substrate 150 to be measured. For example, the sensor passage 219 may be aligned with the selected region of the substrate approximately 130 mm from a center of the substrate 150 to measure an edge portion of the substrate 150. The sensor passage 219 may be sealed at upper and lower ends thereof by a material capable of transmitting light 229, such as quartz or sapphire. In another embodiment, each sensor passage 219 may include a fiber optic cable disposed thereon. It is contemplated that sensor 221 can be employed with process chamber 100 to analyze the substrate-edge, alone or in conjunction with a pyrometer, to measure thin film thickness and other properties of the substrate-edge and temperature of surfaces. Thus, as deposition occurs during processing, the sensors 221 may be used to determine the thickness of film deposited on the edge of the substrate 150.

During processing, light 241 from the light source 244 is used to determine film thickness and/or film thickness deposition rate. The light 241 is directed from the light source 244, for example by a fiber optic cable, to the collimator 215. The collimator 215 then collimates the light 241 and directs the collimated light 243 toward the surface to be measured (e.g., the substrate 150 or thin film disposed thereon). The light 243 is reflected off the surface, as a reflected light 227. The reflected light 227 from the measured surface of the substrate 150 facilitates measurement of film thickness (film thickness growth rate and/or in-film constituent concentration, such as Ge, B, P, and/or Ar etc.). The reflected light 227 travels back to the dichroic mirror 205 and is split into multiple paths (e.g., propagation sub-paths). A first propagation sub-path directs reflected light 211 to the pyrometer 207, while a second propagation sub-path directs reflected light 247 to the collimator 215 and then to the sensor 245. The light intensity collected by the sensor 245 is analyzed for true reflectance, which is compared with film-models, for example (Fresnel equations) using nonlinear fitting equations or other empirically derived equations to determine film thickness.

In one example, film thickness models are empirically derived by obtaining absorption/reflectance data for light at predetermined wavelengths for various films at multiple film thicknesses. The data may be collected at process conditions which approximate those of a predetermined process recipe for processing future substrates, such as a process recipe at which the model will be utilized. The data is then fit to an equation, such as a non-linear equation. Light received by the sensor 245 is analyzed for intensity (e.g., true reflectance of light reflected from the measured specimen) and fit to the empirically derived equation to determine film thickness. Stated otherwise, the amount of light reflected from the substrate 150 surface changes as a function of the thickness of a thin film on the substrate 150 surface. This data and/or equations may also take into account other optical properties, such as refractive index and extinction coefficient, of films to improve measurement accuracy. In one example, film thickness models are derived from the apparatus and/or methods used in U.S. Pat. No. 10,281,261, herein incorporated by reference.

The measured light intensity of the collimated light 213 is used by the sensor 245 to determine a thin film thickness and/or a growth rate of the thin film deposited on the surface of the substrate 150. For example, a lower light intensity may indicate a greater film thickness (as more light is absorbed), and a higher light intensity may indicate a lesser film thickness (as more light is reflected), or vice versa depending on the composition and optical properties of the particular material being measured. The thickness of the deposited film on the surface of the substrate 150 affects the light intensity of the collimated light 213 received by the sensor 245, such that a change in the light intensity can signal a change in the thickness of the deposited film on the surface of the substrate 150.

In certain embodiments, a measurement spectra of the return collimated light 213 may be filtered to provide values indicating measured light intensity only within a selected wavelength range. This range of wavelengths is beneficial because radiation from lamps (such as upper lamps 130) is filtered out to improve measurement accuracy at the sensor 245. The optical filter may be used to block a portion of the reflected light 227 which includes light with a wavelength outside a selected wavelength range. This may occur, for example, when light from the upper lamps 130 (or other lamps) is directed into the pyrometer passage 131, such as by reflecting off of one or more internal chamber surfaces. The inadvertent light may otherwise affect measurements results at the sensor 245, and therefore, filtering the unintended wavelengths improves measurement accuracy.

The sensor 245 may also be used to monitor film growth rate in-situ in the processing chamber 100 and in real-time during substrate processing. In-situ monitoring improves throughput compared to conventional approaches, since substrates need not be removed from the process chamber for thickness measurements to occur. In one example, which can be combined with other examples, the light intensity of the return collimated light 213 is monitored continuously throughout substrate processing, or on predetermined intervals throughout substrate processing. Once a desired film thickness is achieved, the deposition processes is stopped. The substrate 150 may then be removed from the process chamber 100, or further processing may occur within the process chamber 100 according to a process recipe.

The pyrometer 207, one or more additional sensors 221, and sensor 245 may be connected to the controller 196 to facilitate control and/or operations thereof. The controller 196 can store information, data, algorithms, or other control parameters for causing the performance of actions described herein. The controller 196 may report the susceptor assembly 124 characteristics to the spectrometer and can at least instruct the light source 244 to flash. The controller 196 includes a central processing unit (CPU), a memory containing instructions, and support circuits for the CPU. The controller 196 controls various items directly, or via other computers and/or controllers. In one or more embodiments, the controller 196 is communicatively coupled to dedicated controllers, and the controller 196 functions as a central controller.

The CPU in controller 196 may be used for controlling various substrate processing chambers and equipment, and sub-processors thereon or therein. The memory, or non-transitory computer readable medium, is one or more of random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 196 are coupled to the CPU for supporting the CPU. The support circuits include cache, power supplies, clock circuits, input/output circuitry and subsystems, and the like. Operational parameters and instructions are stored in the memory as a software routine that is executed or invoked to turn the controller 196 into a specific purpose controller to control the operations of the process chamber 100 or ISR system 185 described herein. The controller 196 is configured to conduct any of the operations described herein. The instructions stored on the memory, when executed, may cause one or more of operations described herein to be conducted.

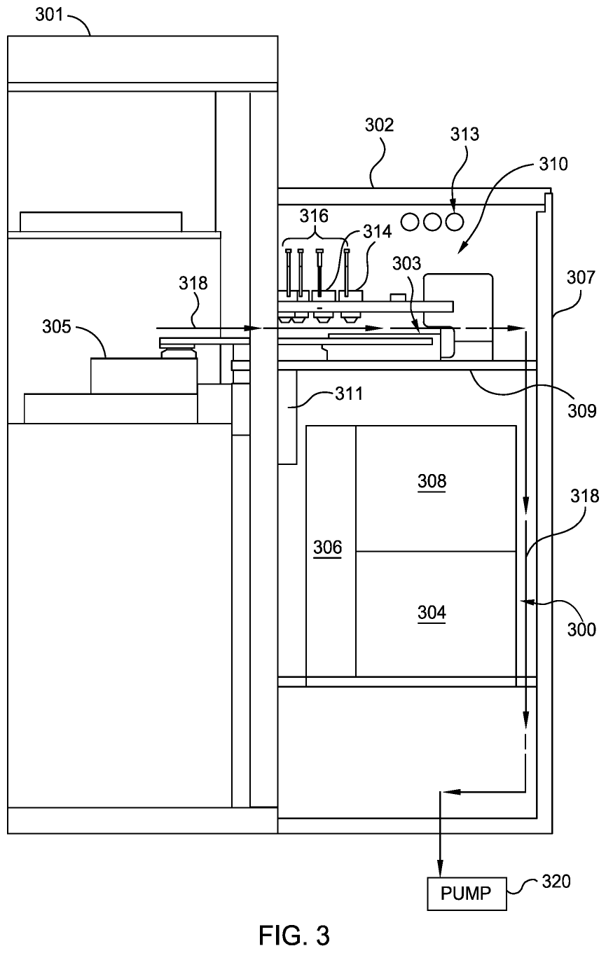

FIG. 3 is a cross-sectional view of an exemplary on-board metrology assembly 300, according to certain embodiments. The on-board metrology assembly 300 may be used to practice the methods described herein. In some embodiments, as shown in FIG. 3, the on-board metrology assembly 300 may be coupled to a processing system, such as a cluster processing system via a factory interface 301 in which a substrate 303 may be transferred to and from the metrology housing 302 via a transfer robot 305. The factory interface 301 may therefore provide a transition between the atmospheric environment of the factory interface 301 and the vacuum environment of the tool or processing chambers of the cluster processing system.

The on-board metrology assembly 300 may be configured to measure film properties, such as film thickness, film composition, sheet resistance, particle count, and film stress, before and/or after processing of the substrate 303. In one implementation, the on-board metrology assembly 300 is configured to measure thickness of a thin film selectively formed on a patterned substrate.

In certain embodiments, the on-board metrology assembly 300 generally includes a light source 304, fiber-optic bundles 306 and a spectrograph 308. The on-board metrology assembly 300 also includes an aligner module 310 disposed on a mounting bracket 309. The mounting bracket 550 may supported by one or more rigid support brackets 311 once the on-board metrology housing 302 is engaged with the factory interface 301. The casing of the on-board metrology housing 133 may include a plurality of perforations 313 for ventilation purposes. The on-board metrology housing 302 may also have a door 307 to allow access and service of the on-board metrology assembly 300 and other connected electronics. The on-board metrology assembly 300 and the aligner module 310 are removable and can be horizontally slid into the on-board metrology housing 302 using any suitable mechanism such as a rack.

Each fiber-optic bundle 306 may include one or more fiber-optic cables. Some of the one or more fiber-optic bundles 306 may be optically connected to the light source 304, and some of the one or more fiber-optic bundles 306 may be optically connected to the spectrograph 308. Some of the fiber-optic bundles 306 may be arranged to transmit light from the light source 304 towards a measuring point on the substrate 303 at normal incidence. Some of the fiber-optic bundles 306 may be coupled to a collimator to collimate the light from the light source 304 to illuminate about, for example, 2 mm in diameter at the measuring point. Such fiber-optic bundles 306 may then capture reflection of the light from the substrate at normal incidence and then transmits that reflection towards the spectrograph 308.

The light source 304 may be a flash light source capable of dispersing pulsed light at short durations. The light source 304 may be a white light source. In one implementation, the light source 304 may be a Xenon flash-lamp. The light source 304 may include a diffuser so the light generated is distributed homogeneously through multiple fiber-optic bundles, such as the fiber-optic bundles 306 and a reference fiber-optic bundle (not shown). The reference fiber-optic bundle may be connected between the light source 304 and the spectrograph 308 to provide a reference channel to cancel out flash-to-flash variations or to compensate any fluctuations/drifts overtime of the light source 304.

In some implementations, the light source 304 may produce ultraviolet (UV) light. In some implementations, light source producing light having more deep ultraviolet (DUV) content may be used. Examples of the light source for producing light having more DUV content are plasma driven light sources or lasers. In some implementation, light having wavelength in infrared range (IR) may be used. The spectrograph 308 may include a charged-coupled device (CCD) array light detector. In one implementation, the spectrograph 308 may measure unpolarized light with a wavelength range between about 200 nm and about 2500 nm, such as between about 200 nm and about 800 nm.

The aligner module 310 generally includes one or more collimators 314 and fiber-optic bundles 316 connected thereto. The aligner module 310 also has an aligner plate with an aligning mechanism (not shown) for rotating a substrate 303. The aligner module 310 of the on-board metrology assembly 300 is disposed at a height corresponding to the movement of the robot 305 to allow transfer of the substrates in and out of the on-board metrology housing 302 without interference with the collimators. During operation, the robot 305 in the factory interface 301 picks up substrate 303 from an atmospheric holding station and places it on the aligning mechanism within the on-board metrology housing 302. The substrate 303 is then rotated by the aligning mechanism to allow thickness measurement on various points along the radii of the substrate using the aligner module 310.

Each of the fiber-optic bundles 316 is coupled to a corresponding collimator 314, respectively. The one or more collimators 314 and fiber-optic bundles 316 connected there to are also in electrical communication with the light source 304, fiber-optic bundles 306 and the spectrograph 308 in order to transmit measurement data. The collimators 314 are mounted at predetermined locations in the on-board metrology housing 302. In one implementation, the collimator 314 may disposed at the center of the aligner plate so that its sensor is focused at the center of the substrate 303. The other collimators 314 may be disposed at locations corresponding to different radial regions of the substrate 303, for example, R 49.33 mm, R 98.67 mm, R 147 mm, and R 148 mm, to measure film thickness at those positions. Different radii are contemplated, depending on the process requirement and/or the size of the substrate. The collimators 314 may also be disposed at specific positions to measure specific regions of the substrate 303 in which a thin film may be selectively deposited on. The substrate can be rotated by any angle to measure thickness of various points along the radii and thus to map for film thickness on the substrate. In one implementation, only four collimators are used in the on-board metrology assembly 300. It is contemplated that more or less collimators are contemplated.

In operation, a robot blade (e.g., the robot 305 shown in FIG. 3) may move the substrate from the atmospheric holding station in the factory interface 301 to the on-board metrology housing 302 containing the on-board metrology assembly 300. The robot 305 places the substrate 303 onto the aligning mechanism where the substrate 303 is rotated to find an alignment marking, such as an alignment notch, on the substrate to allow the substrate to be appropriately oriented within the on-board metrology housing 302 and get ready for measurement. The term orientation or orientation of the substrate refers to a rotational position of the substrate about a central axis of symmetry of the substrate. The light source may then be turned on for about 50 seconds prior to stabilize the light signal from the light source. Alternatively, the light source may be always on to measure film thickness at times until the end of the thickness measurement.

Once the alignment marking is identified and the substrate is stabilized, the pre-turned on light source 304 distributes light homogeneously through the fiber-optic cables to the fiber-optic bundles 306 and the fiber-optic bundles 316, and then to the collimators 314 to illuminate a surface of the substrate 303 for measurement. The fiber-optic cables collect reflected signal from the substrate surface by collimating broadband light in the range of 200-800 nm. During the operation for thickness measurement, the substrate may be illuminated for about 1.5 seconds. The substrate is then rotated by the aligning mechanism 409 counterclockwise or clockwise to perform next measurement on the substrate. In one implementation, six independent measurements are performed by rotating the substrate 50° for each measurement until a 360° rotation of the substrate is completed. For substrate stability, there may be a predetermined waiting period (based on vibrational information and tool test) after each rotation and before the next measurement is performed.

The collection of reflected signal and corresponding measurement of thickness for a particular orientation of the substrate may continue for a period of time, such as about 1.5 seconds for 15 data-points of thickness, in order to obtain an averaged thickness of the thin film using either all data-points or desired number of data-points for that particular location on wafer. The substrate then may be rotated by any desired angle, such as 50 degrees, for the thickness measurement on the next locations. Signal collection and thickness measurement may be stopped for the period while the target substrate rotates and stabilizes. The rotation of the target substrate and measurement may be continued until the desired numbers of rotation, such as 4 rotations, are completed and the corresponding thicknesses are obtained. A thin film thickness map on the substrate may be generated using the thickness measured through all these rotations

Once the measurement is finished, the substrate is transferred by the robot 305 from the on-board metrology housing 302 back to the atmospheric holding station. This measurement procedure may be repeated on the next substrate received in the on-board metrology housing 302 until all or a desired number of substrates are processed. Measurement and analysis of reflectance of the thin film may be conducted simultaneously in a server where the thickness information, film morphology, and/or other parameters of the thin film are monitored in about real time. In some embodiments, adjustments to processing may be implemented as a result of the monitoring thin film measurement and analysis data. In such instances, adjustments may be implemented for subsequent substrates being processed in the process chamber through a feed-forward algorithm.

While not shown, an exhaust duct/channel with perforated sheets may be provided inside the on-board metrology housing 302 so that compressed air from the factory interface 301 enters and leaves the on-board metrology housing 302 smoothly without recirculation. For example, the exhaust duct/channel may be provided at locations along the on-board metrology housing 302. The exhaust duct/channel is provided such that a laminar flow 318 is introduced from the factory interface 301 into the on-board metrology housing 302. The laminar flow 318 is maintained above the substrate 303 so that no particles are accumulated on the substrate which can affect the measurement and/or final chip. By maintaining laminar flow inside the on-board metrology housing 302, any outgassing from the substrate 303 can be exhausted, thereby preventing degradation of the one or more collimators 314. The laminar flow 318 is then pumped out of the on-board metrology housing 302 through a pump 320. It is contemplated that the laminar flow 318 may include any suitable inert gas, such as argon or helium.

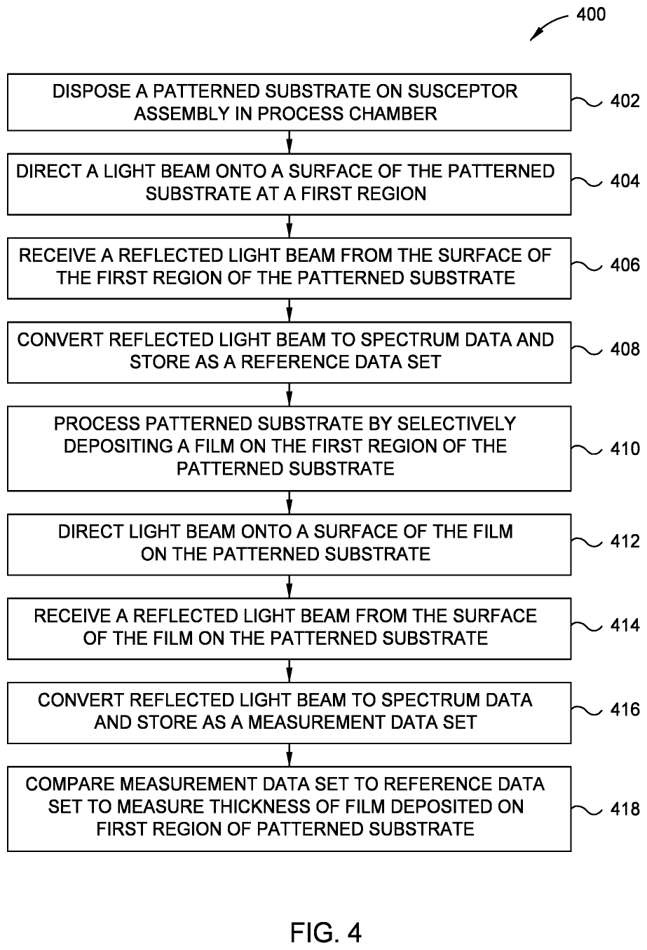

FIG. 4 is a schematic block diagram of a method 400 for measuring a thickness of a thin film selectively deposited on a patterned substrate in a process chamber, such as process chamber 100 depicted in FIGS. 1 and 2. The method 400 is described with respect to FIGS. 1, 2, and 5A-5F to facilitate explanation, but it is contemplated that the method 400 may be used with systems and chambers other than process chamber 100 of FIGS. 1 and 2.

It is further contemplated that the controller 196 may instruct or otherwise control one or more aspects of the method 400. For example, the controller 196 may instruct the process chamber 100 and the ISR system 185 to perform measurements and receive and process measurement data from the ISR system 185 to obtain thickness measurements of films deposited on the patterned substrate.

In certain embodiments, the patterned substrate may be a silicon substrate having multiple layers (e.g. film stacks) utilized to form different patterns and/or features. The substrate may be a material such as crystalline silicon, silicon oxide, strained silicon, silicon germanium, doped or undoped polysilicon, doped or undoped silicon wafers and patterned or non-patterned substrates, silicon on insulator (SOI), carbon doped silicon oxides, silicon nitride, doped silicon, germanium, gallium arsenide, glass, sapphire, metal layers disposed on silicon and the like. The patterned substrate may be of various shapes and dimensions, such as 200 mm, 300 mm, or 450 mm diameter wafers, or rectangular or square panels.

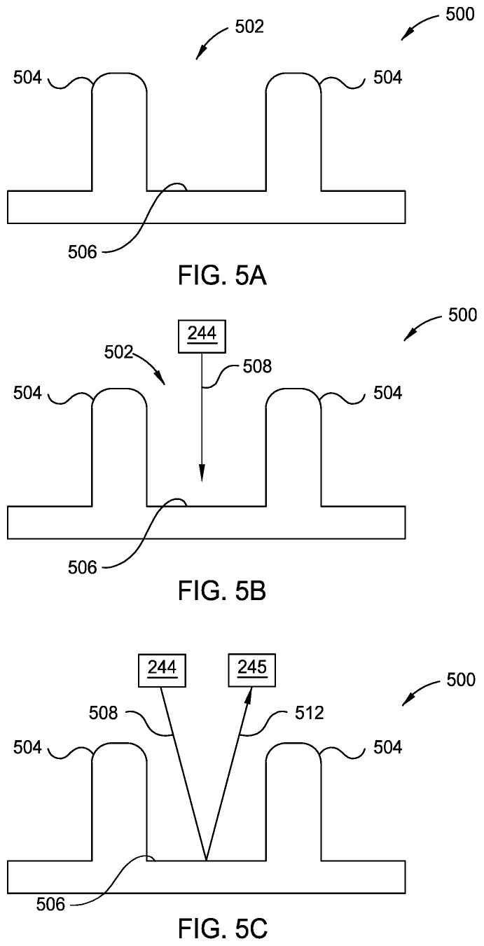

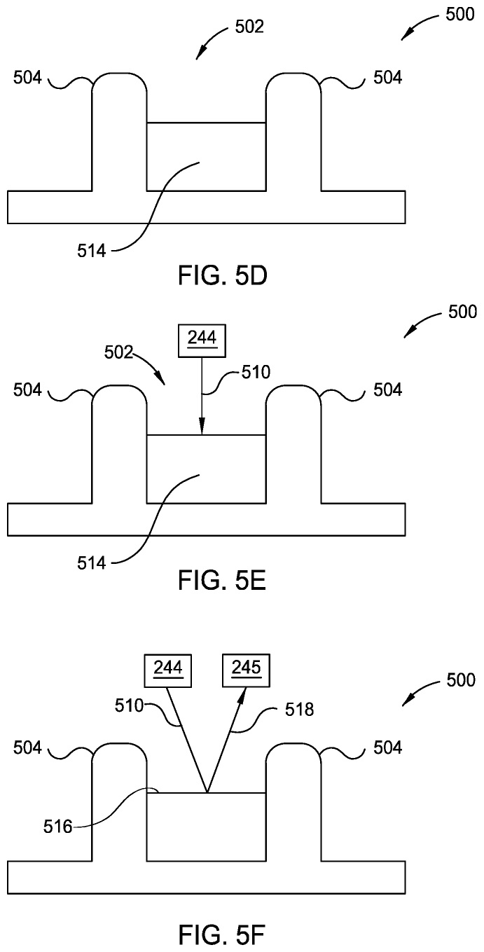

The method 400 begins at operation 402, in which a patterned substrate 500 is disposed on susceptor assembly 124 in process chamber 100. The patterned substrate 500 may be a silicon substrate having one or more layers formed thereon to form one or more structures or features, such as a shallow trench isolation (STI) structures (“trench 502”) formed between structures 504 flanking the trench 502, as shown in FIG. 5A. The trench 502 includes a bottom surface 506 disposed between the structures 504. Although FIG. 4A shows patterned substrate 500 having a single feature or trench 502 for illustrative purposes, those skilled in the art will understand that there can be more than one feature or trench 502.

At operation 404, ISR system 185 integrated with process chamber 100 directs a light beam 508 from the light source 244 towards a surface of the patterned substrate 500, such as the bottom surface 506 of the trench 502 of the patterned substrate 500 as shown in FIG. 5B. Light beam 508 from the light source 244 of ISR system 185 may be provided at a known intensity and wavelength (or range of wavelengths), such as the range or wavelengths measured by sensor 245. After light beam 508 reaches the bottom surface 506 of trench 502, light beam 508 is reflected from the bottom surface 506 back towards ISR system 185 as a reflected light beam 512.

Operation 406 continues with receiving the reflected light beam 512 from the patterned substrate 500 by sensor 245 of the ISR system 185, as shown in FIG. 5C. As discussed above, sensor 245 may be a spectrometer that converts the reflected light beam 512 received to reference spectrum data, such as for example data related to the wavelength or intensity of the reflected light beam 512. In operation 408, the reference spectrum data is used to create a reference data set for in-situ reflectometry. In some embodiments, the reference data set may be associated with the reflected light beam 512 based on intensity, wavelength, frequency, amplitude, phase shift, and/or fit to a function. The reference data set may be stored in the controller 196 or a memory connected thereto.

In operation 410, a selective deposition process is performed in process chamber 100 to selectively deposit a thin film 514 in each of the one or more trenches 502 of the patterned substrate 500, as shown in FIG. 5D.

At operation 412, a light beam 510 from the light source 244 is directed by the ISR system 185 towards a top surface 516 of the thin film 514 deposited in trench 502, as shown in FIG. 5E. Similar to operation 404, light beam 510 from the light source 244 may be provided at a known intensity and wavelength (or range of wavelengths), such as the range or wavelengths measured by sensor 245. Light beam 510 is then reflected from the top surface 516 of the thin film 514 as a reflected light beam 518.

At operation 414, as shown in FIG. 5F, the reflected light beam 518 from the thin film 514 is received by the sensor 245 and converted to spectrum data. In operation 416, the spectrum data from the reflected light beam 518 is used to create a measurement data set corresponding to the thin film 514 measured via in-situ reflectometry. In some embodiments, the measurement data set may be associated with the reflected light beam 518 based on intensity, wavelength, frequency, amplitude, phase shift, and/or fit to a function. The measurement data set may also be stored in and utilized by the controller 196 for comparison with the reference data set.

At operation 418, the measurement data set is compared to the reference data set obtained in operation 408 to determine a difference in the intensities between the reflected light beam 512 from the bottom surface 506 of the trench 502 and the reflected light beam 518 from the top surface 516 of the thin film 514 deposited on the bottom surface 506 in trench 502. Since the thickness of the deposited film on the surface of the substrate 150 affects the light intensity of the reflected light received by the sensor 245, data corresponding to a change in the intensity of the reflected light from the top surface 516 of thin film 514 can be used to determine a thickness of the thin film 514 deposited on the bottom surface 506 of the patterned substrate 500.

In some embodiments, light from the light source 244 may be triggered by a controller instruction during or after the selective deposition process in operation 410, or in response to a physical trigger (e.g., a contact switch) by a user. It is contemplated in the present disclosure that by performing operations 412-518 concurrently during the selective deposition process in operation 410, the thickness of the thin film 514 being deposited may be monitored in real time during processing of the patterned substrate 500.

In certain embodiments, the present disclosure contemplates that operations 410-418 of method 400 may be repeated for additional patterned substrates similar to patterned substrate 500 being processed in which thin film 514 is selectively deposited and measured via in-situ reflectometry using the same reference data set obtained and stored in operation 408.

In some embodiments, operation 414 of method 400 may include recording an angular position of the susceptor assembly 124 at the time light is provided from the light source 24 to record an association between the angular position of the susceptor assembly 124 and light for measurements of the patterned substrate. The angular position of the susceptor assembly 124 can be determined, for example, by rotating the susceptor assembly 124 with an actuator of known angular position (for example, using a step encoder). Additionally or alternatively, an angular position of the susceptor assembly 124 can be determined using optical signals. In such an example, the shaft 155 of the susceptor assembly 124 may include a reflector on a portion thereof. As the shaft 155 rotates, an optical signal may be provided to and received by the sensor 245 to determine an angular position of the shaft 155. It is contemplated that other methods of determining angular position may be utilized, such as the use of a stepper motor with steps of known angular distance.

In another example, the susceptor assembly 124 may be rotated at a constant specified rate, while a stage encoder provides data related to the angular position of the susceptor assembly 124 to the controller 196. The controller 196 causes light from the light source 244 to be directed to the substrate at a predetermined interval, and the controller 196 associates each data spectrum collected by the sensor 245 with the known angular position of the susceptor assembly 124. In such an example, a trigger for initiating propagation of light from the light source 244 may be omitted, thereby simplifying hardware and reducing costs.

In some embodiments, operation 416 may include the controller 196 associating the received spectrum data with the angular positions of the susceptor assembly 124. Spectrum data which is inconsistent may be attributed to unintended movements of the susceptor assembly 124 (e.g. swaying or wobbling) and the substrate thereon during processing. The in-plane movement of the substrate may unintentionally change the distance of the propagation path between the sensors within the ISR system 185 (e.g., sensor 245, pyrometer 207, and additional sensors 221) and the specimen being measured (e.g., the substrate 500 or thin film 514 disposed thereon). The change in distance of the propagation path may affect measurement accuracy and thus film thickness measurement accuracy. However, in certain embodiments, the controller 196 can determine corrective factors for each angular position of the susceptor assembly 124 to account for the unintended movement. Thus, as the sensor 245 receives data during processing of the substrates, the corrective factors are applied to received measurements to account for substrate movement and variations induce by rotating members, thereby improving the accuracy of film thickness measurements.

In some embodiments, the combination of angular positions, angular rotation, and spectrum data may be used to assist in creating the reference data set for in-situ reflectometry in operation 408. In some aspects, machine learning or artificial intelligence can be applied to improve the collection and application of the data set for improved thin film measurement.

In yet other embodiments, it is contemplated that collecting of data related to the angular positions may be omitted. In such an example, no correction of unintended movements of the substrate assembly 124 or the patterned substrate 500 may be applied. In other embodiments, measurements obtained in method 400 may be normalized to reduce error attributable to issues stemming from at least movement caused by rotation, machining tolerances, manufacturing limitations, material properties, wear on the system, and other possible sources of error.

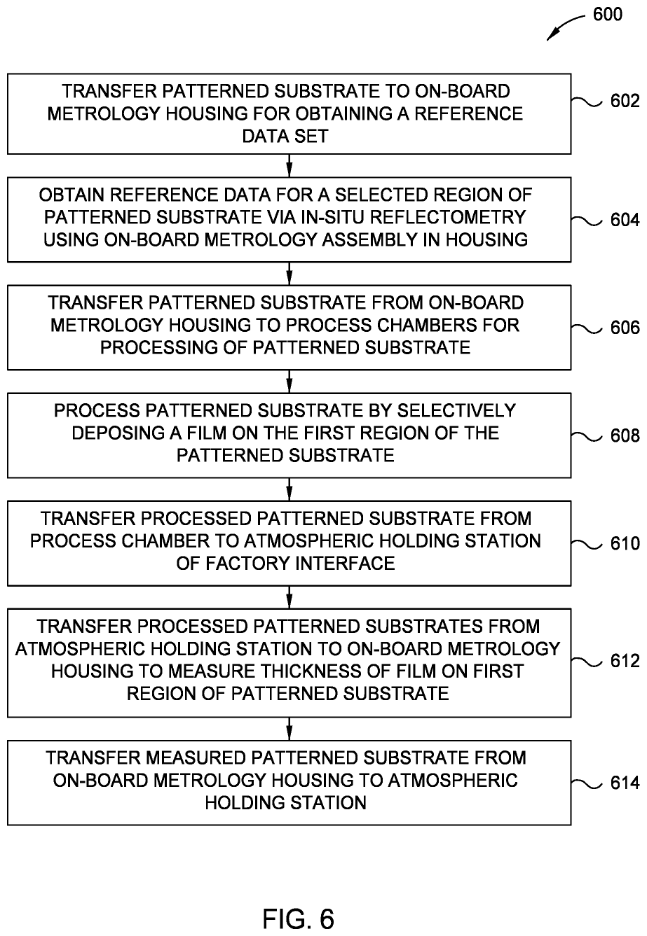

FIG. 6 is a schematic block diagram of a method 600 for measuring a thickness of a thin film selectively deposited on a patterned substrate in an onboard metrology assembly, such as the on-board metrology assembly 300 depicted in FIG. 3. The method 600 is described with respect to FIG. 3 to facilitate explanation, but it is contemplated that the method 600 may be used with systems and assemblies other than the on-board metrology assembly of FIG. 3.

It is further contemplated that the controller 196 may instruct the patterned substrate to be transferred from the process chamber 100 to the on-board metrology housing 302 for the on-board metrology assembly 300 to perform measurements via reflectometry (e.g. in-situ reflectometry type technique), receive and process measurement data from the on-board metrology assembly 300, and obtain thickness measurements of films deposited on the patterned substrate.

The method 600 begins at operation 602 in which a patterned substrate may be transferred to the on-board metrology housing 302. The patterned substrate may be transferred from the factory interface 301 coupled to the metrology housing 302 by a transfer robot 305.

At operation 604, an on-board metrology assembly 300 in the metrology housing 302 obtains a reference data set from a selected region of the patterned substrate to be processed using the on-board metrology assembly 300. The reference data set may be obtained via reflectometry using the on-board metrology assembly 300 and the aligner module 310.

In some embodiments, the placement of the patterned substrate in the on-board metrology housing 302 may be adjusted to align the patterned substrate with the aligner module 310. In certain embodiments, the patterned substrate may be adjusted by aligning the placement of the patterned substrate in the on-board metrology housing based on mapping and positioning of similar structures of previously processed and measured patterned substrates (e.g., similar scribe, pad, etc.) for measuring the same selected region of the patterned substrate.

At operation 606, after obtaining the reference data from the patterned substrate, the patterned substrate is transferred from the on-board metrology housing 302 to a process chamber of the processing system for processing of the patterned substrate. In one example, the patterned substrate is transported to a deposition process chamber, such as an epitaxial deposition chamber in which a thin film is selectively deposited on the patterned substrate.

The patterned substrate may be a silicon substrate having one or more layers formed thereon to form one or more structures or features, such as a shallow trench isolation (STI) structures (“trench”) formed on the patterned substrate. In operation 604, the process chamber may selectively deposit the thin film in the trench of the patterned substrate.

At operation 608, after the processing of the patterned substrate, a transfer robot may transfer the patterned substrate from the process chamber to an atmospheric holding station of the factory interface 301 until the other subsequently processed substrates are finished with their deposition processing.

At operation 610, the processed patterned substrates are transferred by the transfer robot 305 from the atmospheric holding station to the on-board metrology housing 302 coupled to the factory interface 301.

At operation 612, the on-board metrology assembly 300 in the on-board metrology housing 302 then measures a thickness the thin film deposited in the trench of the patterned substrate. The thickness of the thin film may be determined by obtaining a measuring data set using the on-board metrology assembly 300 via reflectometry and comparing the measuring data set with the reference data set obtained in operation 602. As discussed above, data corresponding to a change in the intensity of the reflected light from a top surface of the thin film deposited on the patterned substrate can be used to determine a thickness of the thin film.

Once all the substrates or a desired number of substrates are done with corresponding measurements, at operation 614, the patterned substrates are transferred by the transfer robot 305 from the on-board metrology housing 302 to the atmospheric holding station of the factory interface 301.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A method for measuring film properties on a substrate, comprising:
placing a substrate on a substrate support in a process chamber having an in-situ reflectometry system integrated with the process chamber;
establishing a reference data set via in-situ reflectometry using the in-situ reflectometry system for a selected region of the substrate;
processing the substrate by selectively depositing a film on the selected region of the substrate;
establishing a measurement data set via in-situ reflectometry using the in-situ reflectometry system for the film deposited on the selected region of the substrate; and
determining a thickness of the film by comparing the measurement data set with the reference data set.

2. The method of claim 1, wherein establishing the reference data set using the in-situ reflectometry system comprises:
directing a first light beam from a light source of the in-situ reflectometry system onto a surface of the substrate at the selected region, the first light beam reflecting off the surface of the substrate to produce a first reflected light beam;
receiving the first reflected light beam using a spectrometer of the in-situ reflectometry system; and
recording an intensity of the first reflected light beam as the reference data set.

3. The method of claim 1, wherein establishing the measurement data set using the in-situ reflectometry system for the film comprises:
directing a second light beam from a light source onto a surface of the film deposited on the substrate at the selected region, the second light beam reflecting off the surface of the film to produce a second reflected light beam;
receiving the second reflected light beam using a spectrometer of the in-situ reflectometry system; and
recording an intensity of the second reflected light beam as the measurement data set.

4. The method of claim 1, wherein the selected region comprises an open area of about 5% of the substrate.

5. The method of claim 1, wherein the substrate comprises a patterned substrate, and selectively depositing the film on the selected region of the substrate comprises selectively depositing the film in a trench formed on a top surface of the patterned substrate.

6. The method of claim 1, further comprising:
establishing a monitoring data set via in-situ reflectometry using the in-situ reflectometry system concurrently while the film is being deposited on the selected region of the substrate; and
determining a thickness of the film deposited by comparing the measurement data set with the reference data set for real-time monitoring of the film during processing of the substrate.

7. The method of claim 1, wherein comparing the measurement data set with the reference data set to determine the thickness of the film comprises analyzing a change in intensity of a reflected light from a surface of the selected region of the substrate and a surface of the film deposited on the selected region of the substrate.

8. The method of claim 1, wherein the substrate comprises a patterned substrate with a non-planarized top surface and unknown surface or material properties.

9. The method of claim 1, further comprising a controller connected to the in-situ reflectometry system, the controller recording one or more angular position of the substrate support when a first light beam is provided from a light source of the in-situ reflectometry system during the establishing of the reference data set, when a second light beam is provided from the light source of the in-situ reflectometry system during the establishing of the reference data set establishing the measurement data set, and during the processing the substrate as the substrate support is being rotated, and wherein the controller associates wavelengths or intensities of reflected light from the first and second light beams to one of the one or more angular positions of the substrate support.

10. The method of claim 1, wherein the reference data set and measurement data set are associated with light reflected off of the substrate and the film, respectively, based on variables comprising:
intensity;
wavelength;
frequency;
amplitude;
phase shift; and
fit to a function.

11. A method for measuring film properties on a substrate, comprising:
disposing a substrate in an on-board metrology housing having an on-board metrology assembly;
establishing a reference data set via reflectometry using the on-board metrology assembly for a selected region of the substrate;
transferring the substrate from the on-board metrology housing to a process chamber;
processing the substrate by selectively depositing a film on a surface of the substrate at the selected region;
transferring the substrate from the process chamber to the on-board metrology housing;
establishing a measurement data set via reflectometry using the on-board metrology assembly for the film deposited at the selected region of the substrate; and
determining a thickness of the film by comparing the measurement data set with the reference data set.

12. The method of claim 11, wherein establishing the reference data set using the on-board metrology assembly comprises:
directing a first light beam from a light source of the on-board metrology assembly onto a surface of the substrate at the selected region, the first light beam reflecting off the surface of the substrate to produce a first reflected light beam;
receiving the first reflected light beam using a spectrometer of the on-board metrology assembly; and
recording an intensity of the first reflected light beam as the reference data set.

13. The method of claim 11, wherein establishing the measurement data set using the on-board metrology assembly for the film comprises:
directing a second light beam from a light source of the on-board metrology assembly onto a surface of the film deposited on the substrate at the selected region, the second light beam reflecting off the surface of the film to produce a second reflected light beam;
receiving the second reflected light beam using a spectrometer of the on-board metrology assembly; and
recording an intensity of the second reflected light beam as the measurement data set.

14. The method of claim 11, wherein the selected region comprises an open area of about 5% of the substrate.

15. The method of claim 11, wherein the substrate comprises a patterned substrate, and selectively depositing the film on the selected region of the substrate comprises selectively depositing the film in a trench formed on a top surface of the patterned substrate.

16. The method of claim 11, wherein comparing the measurement data set with the reference data set to determine the thickness of the film comprises analyzing a change in intensity of a reflected light from a surface of the selected region of the substrate and a surface of the film deposited on the selected region of the substrate.

17. The method of claim 11, wherein the substrate comprises a patterned substrate with a non-planarized top surface and unknown surface or material properties.

18. The method of claim 11, further comprising a controller connected to the on-board metrology assembly, the controller recording one or more angular position of the substrate when a first light beam is provided from a light source of the on-board metrology assembly during the establishing of the reference data set, when a second light beam is provided from the light source of the on-board metrology assembly during the establishing of the measurement data set, and during the processing the substrate as the substrate is being rotated, and wherein the controller associates wavelengths or intensities of reflected light from the first and second light beams to one of the one or more angular positions of the substrate.

19. The method of claim 11, wherein establishing the reference data further comprises generating and storing data corresponding to specific angular rotations of the substrate.

20. The method of claim 11, further comprising aligning placement of the substrate in the on-board metrology housing based on mapping and positioning of similar structures on a patterned substrate for measuring the selected region of the substrate.
